(19) United States
(12) Patent Application Publication
(10) Pub. No.: US 2023/0411161 A1
(43) Pub. Date: Dec. 21, 2023

(54) METHOD OF FORMING A WIRING STRUCTURE, METHOD OF MANUFACTURING A SEMICONDUCTOR DEVICE USING THE SAME, AND SEMICONDUCTOR DEVICE MANUFACTURED BY THE SAME METHOD

(71) Applicant: SAMSUNG ELECTRONICS CO., LTD., Suwon-si (KR)

(72) Inventors: Minsik KIM, Suwon-si (KR); Gwanhyoung LEE, Seoul (KR); Sukhoon KIM, Suwon-si (KR); Yongjun SHIN, Seoul (KR)

(73) Assignee: SEOUL NATIONAL UNIVERSITY R&DB FOUNDATION, Seoul (KR)

(21) Appl. No.: 18/196,098

(22) Filed: May 11, 2023

(30) Foreign Application Priority Data
May 31, 2022 (KR) 10-2022-0066516
Jul. 26, 2022 (KR) 10-2022-0092552

(51) Int. Cl. H01L 21/3065; H01L 29/20; H01L 29/423; H01L 21/768; H01L 21/311; H01L 21/02

(52) U.S. Cl. CPC H01L 21/3065; H01L 29/2003; H01L 29/42364; H01L 21/02107; H01L 21/76897; H01L 21/31116; H01L 21/76829

(57) ABSTRACT

In a method, an electrode layer and an insulation layer are alternately and repeatedly stacked on a substrate. A first insulation layer is etched through a first dry etching process using an etching gas including fluorine to form an opening exposing a first electrode layer. The first electrode layer exposed by the opening is partially removed through an RIE process using oxygen and/or hydrogen plasma to enlarge the opening so that a second insulation layer is exposed. The second insulation layer exposed by the opening is etched through a second dry etching process using an etching gas including fluorine to enlarge the opening so that a second electrode layer is exposed. A contact plug is formed in the enlarged opening.

### CROSS-REFERENCE TO RELATED APPLICATION

This application claims priority under 35 USC § 119 to Korean Patent Application Nos. 10-2022-0066516 and 10-2022-0092552, filed on May 31, 2022 and Jul. 26, 2022, respectively, in the Korean Intellectual Property Office (KIPO), the contents of which are herein incorporated by reference in their entirety.

### BACKGROUND

### 1. Field

Example embodiments relate to a method of forming a wiring structure, a method of manufacturing a semiconductor device using the same, and a semiconductor device manufactured by the same method.

### 2. Description of the Related Art

A channel including silicon may be used in a semiconductor device, however, as the size of semiconductor devices decreases, the electrical characteristics of the channel including silicon may reach a limit. Thus, a channel including a 2-dimensional material having higher charge mobility than silicon has been developed, and an electrode including graphene has been developed. However, more study is need in order that the electrode including graphene may be used in the semiconductor device.

### SUMMARY

The embodiments may be realized by providing a method of forming a wiring structure, the method comprising alternately and repeatedly stacking electrode layers and insulation layers on a substrate, the electrode layers including graphene and the insulation layer including hexagonal boron nitride (h-BN); etching a first insulation layer through a first dry etching process using an etching gas including fluorine (F) to form an opening exposing an upper surface of a first electrode layer, the first insulation layer being an uppermost one of the insulation layers, and the first electrode layer being an uppermost one of the electrode layers; removing a portion of the first electrode layer exposed by the opening through a reactive ion etching (RIE) process using oxygen plasma and/or hydrogen plasma to enlarge the opening so that an upper surface of a second insulation layer is exposed, the second insulation layer being one of the insulation layers directly under the first electrode layer; etching the second insulation layer exposed by the opening through a second dry etching process using an etching gas including fluorine (F) to enlarge the opening so that an upper surface of a second electrode layer is exposed, the second electrode layer being one of the electrode layers directly under the second insulation layer; and forming a contact plug in the enlarged opening

The embodiments may be realized by providing a method of forming a wiring structure, the method including forming a first channel on a substrate; forming first source/drain electrodes on the substrate to cover lateral portions, respectively, of the first channel, each of the first source/drain electrodes including graphene forming a first insulation layer on the substrate to cover the first channel and the first source/drain electrodes forming a gate electrode on the first insulation layer, the gate electrode including graphene forming a second channel on the second insulation layer; forming second source/drain electrodes on the second insulation layer to cover lateral portions of the second channel, each of the second source/drain electrodes including graphene; forming a third insulation layer on the second insulation layer to cover the second channel and the second source/drain electrodes; forming a first contact plug through the third insulation layer to contact an upper surface of a first one of the second source/drain electrodes at a first side of the second channel; forming a second contact plug through the first to third insulation layers to contact an upper surface of a first one of the first source/drain electrodes at a first side of the first channel; forming a third contact plug through the first to third insulation layers and a second one of the second source/drain electrodes at a second side of the second channel to contact an upper surface of a second one of the first source/drain electrodes at a second side of the first channel; and forming a fourth contact plug through the second and third insulation layers to contact an upper surface of the gate electrode.

The embodiments may be realized by providing a semiconductor device, comprising a first insulation layer on a substrate; a first channel on the first insulation layer; first source/drain electrodes contacting opposite lateral portions, respectively, of the first channel and portions of the first insulation layer adjacent thereto, each of the first source/drain electrodes including graphene; a second insulation layer on the first insulation layer, the second insulation layer covering the first channel and the first source/drain electrodes; a gate electrode on the second insulation layer, the gate electrode including graphene; a third insulation layer on the second insulation layer, the third insulation layer covering the gate electrode; a second channel on the third insulation layer; second source/drain electrodes contacting opposite lateral portions, respectively, of the second channel and portions of the third insulation layer adjacent thereto, each of the second source/drain electrodes including graphene; a fourth insulation layer on the third insulation layer, the fourth insulation layer covering the second channel and the second source/drain electrodes; a first contact plug extending through the fourth insulation layer and contacting an upper surface of a first one of the second source/drain electrodes at a first side of the second channel; a second contact plug extending through the second to fourth insulation layers and contacting an upper surface of the first source/drain electrode at a first side of the first channel; a third contact plug extending through the second to fourth insulation layers and a second one of the second source/drain electrodes at a second side of the second channel and contacting an upper surface of the first source/drain electrode at a second side of the first channel; and a fourth contact plug extending through the third and fourth insulation layers and contacting an upper surface of the gate electrode

### BRIEF DESCRIPTION OF THE DRAWINGS

Features will become apparent to those of skill in the art by describing in detail exemplary embodiments with reference to the attached drawings in which:

FIGS. 1 to 5 are cross-sectional views illustrating a method of forming a wiring structure in accordance with example embodiments.

FIGS. 6 to 23 are plan views and cross-sectional views illustrating a method of manufacturing a semiconductor device in accordance with example embodiments.

### DETAILED DESCRIPTION

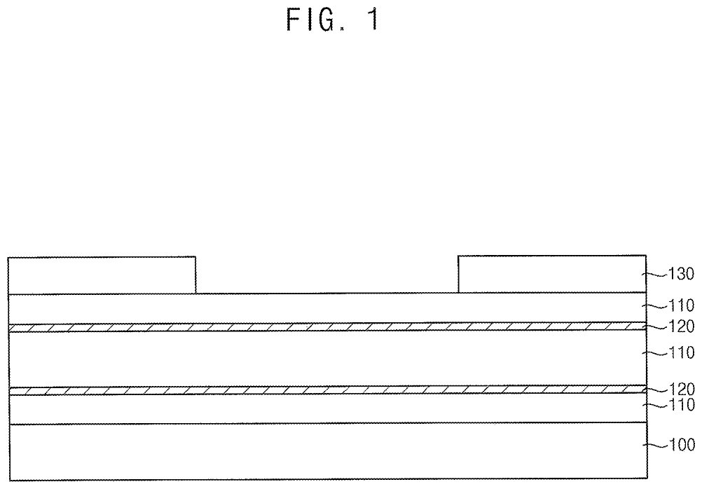

FIGS. 1 to 5 are cross-sectional views illustrating a method of forming a wiring structure in accordance with example embodiments.

Referring to FIG. 1, an insulation layer 110 and an electrode layer 120 may be alternately and repeatedly stacked on a substrate 100, and a first mask 130 may be formed on an uppermost one of the insulation layers 110.

FIG. 1 shows that three insulation layers 110 and two electrode layers 120 are alternately and repeatedly stacked on the substrate 100, however, embodiments may not be limited thereto.

The substrate 100 may include a semiconductor material, e.g., silicon, germanium, silicon-germanium, etc., or an insulating material, e.g., silicon oxide.

The insulation layer 110 may include, e.g., hexagonal boron nitride (h-BN), silicon oxide, silicon nitride, etc. The electrode layer 120 may include, e.g., graphene. The first mask 130 may include, e.g., polymethyl methacrylate (PMMA) in a form of a photoresist pattern, etc.

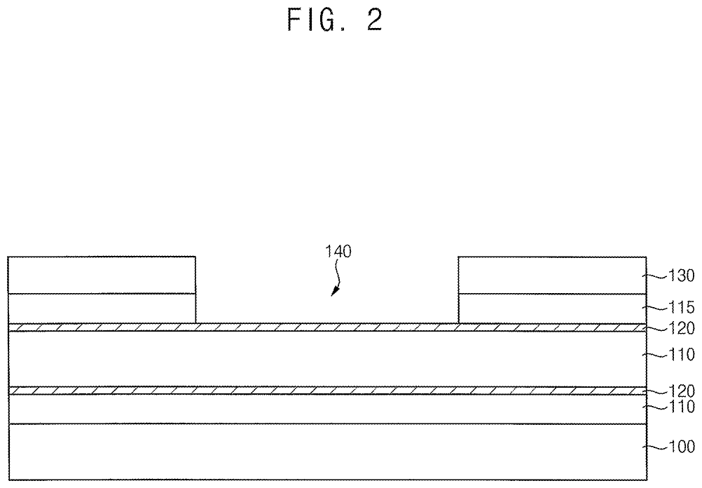

Referring to FIG. 2, a first dry etching process may be performed using the first mask 130 as an etching mask on the uppermost one of the insulation layers 110, and thus a first opening 140 may be formed to expose an upper surface of an upper one of the electrode layers 120. The uppermost one of the insulation layers 110 may be patterned to form an insulation pattern 115.

In example embodiments, the first dry etching process may be performed using an etching gas including fluorine (F), e.g., xenon difluoride (XeF₂), carbon tetrafluoride (CF₄), sulfur hexafluoride (SF₆), etc. Thus, the upper surface of the upper one of the electrode layers 120 exposed by the first dry etching process may be fluorinated to form fluorinated graphene, which may serve as an etch stop layer in the first dry etching process. Accordingly, during the first dry etching process, an upper portion of the insulation layer 110 under the upper one of the electrode layers 120 may not be removed.

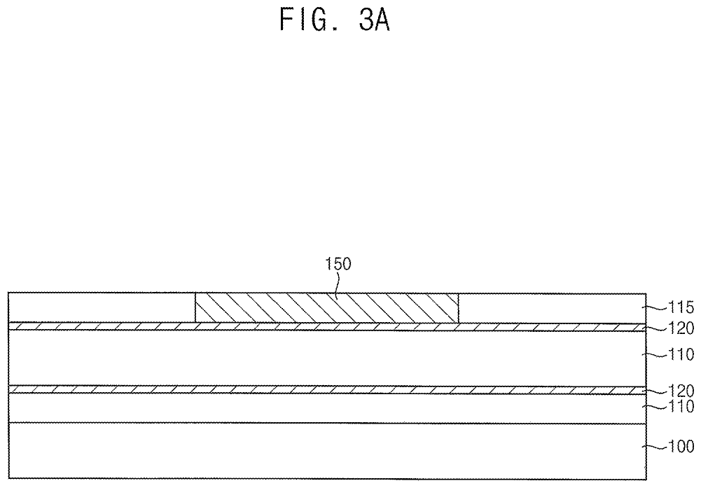

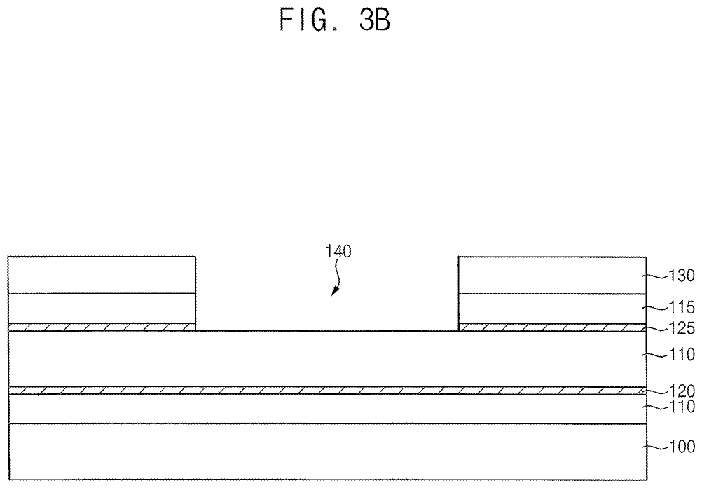

Referring to FIG. 3A, for example, an ashing process and/or a stripping process may be performed to remove the first mask 130. A first conductive layer may be formed on the exposed upper surface of the upper one of the electrode layers 120 and an upper surface of the insulation pattern 115 to fill the first opening 140. A planarization process may be performed on the first conductive layer until the upper surface of the insulation pattern 115 is exposed.

Thus, a first contact plug 150 may be formed in the first opening 140 to contact the upper surface of the upper one of the electrode layers 120.

The planarization process may include, e.g., a chemical mechanical polishing (CMP) process and/or an etch back process.

The first conductive layer may include a metal, e.g., copper, aluminum, ruthenium, titanium, tantalum, chromium, palladium, etc.

Referring to FIG. 3B, in some implementations, the exposed portion of the upper one of the electrode layers 120 may be removed by, e.g., a reactive ion etching (RIE) process, such that an electrode 125 may be formed.

The RIE process may be performed using, e.g., oxygen plasma, hydrogen plasma, etc.

Hereinafter, a case in which the electrode 125 is formed is explained.

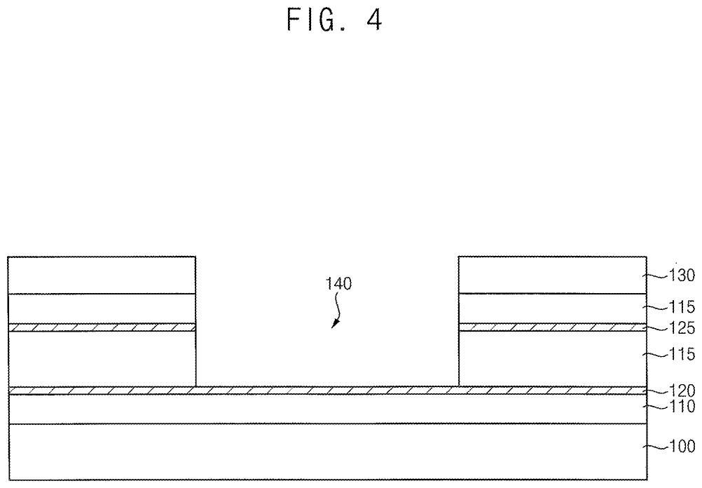

Referring to FIG. 4, processes substantially the same as or similar to those illustrated with reference to FIG. 2 may be performed.

For example, a second dry etching process may be performed using the first mask 130, the insulation pattern 115, and the electrode 125 under the first mask 130 as an etching mask on a middle one of the insulation layers 110 such that the first opening 140 may be enlarged downwardly to expose an upper surface of a lower one of the electrode layers 120. The middle one of the insulation layers 110 may be patterned to form an insulation pattern 115.

The second dry etching process may be performed using an etching gas including fluorine (F), e.g., xenon difluoride (XeF₂), carbon tetrafluoride (CF₄), or sulfur hexafluoride (SF₆), etc. Thus, the upper surface of the lower one of the electrode layers 120 exposed by the second dry etching process may be fluorinated to form fluorinated graphene, which may serve as an etch stop layer in the second dry etching process. Accordingly, during the second dry etching process, an upper portion of the insulation layer 110 under the lower one of the electrode layers 120 may not be removed.

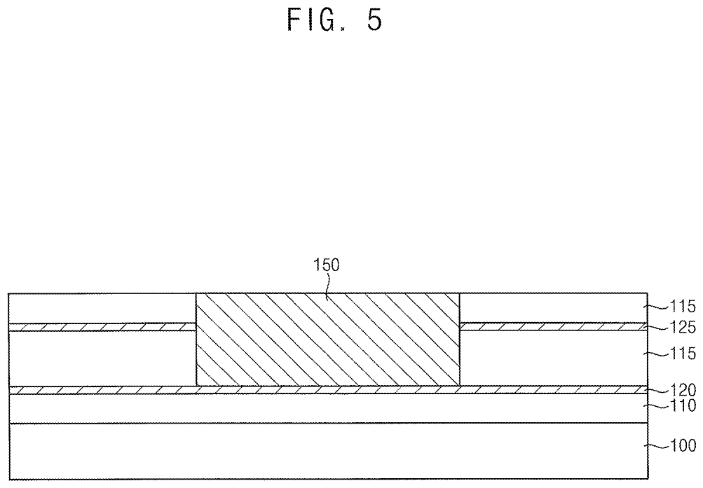

Referring to FIG. 5, processes substantially the same as or similar to those illustrated with reference to FIG. 3A may be performed.

For example, after removing the first mask 130, a second conductive layer may be formed on the exposed upper surface of the lower one of the electrode layers 120 and an upper surface of an upper one of the insulation patterns 115 to fill the first opening 140, and a planarization process may be performed on the second conductive layer until the upper surface of the upper one of the insulation patterns 115 is exposed. Thus, the first contact plug 150 may be formed in the first opening 140 to contact the upper surface of the lower one of the electrode layers 120.

The first contact plug 150 may contact the upper surface of the lower one of the electrode layers 120 and a sidewall of the electrode 125.

By the above processes, the wiring structure including the lower one of the electrode layers 120, the electrode 125 and the first contact plug 150 may be manufactured.

As illustrated above, in a stack structure including the insulation layers 110 and the electrode layers 120 alternately and repeatedly stacked, one of the insulation layers 110 may be selectively etched by a dry etching process using an etching gas having an etching selectivity between the insulation layer 110 and the electrode layer 120, that is, an etching gas including fluorine (F) so that one of the electrode layers 120 under the one of the insulation layers 110 may not be removed, and further, one of the insulation layers 110 under the one of the electrode layers 120 also may not be removed.

Additionally, one of the electrode layers 120 may be selectively etched by an RIE process using oxygen plasma or hydrogen plasma having an etching selectivity between the insulation layer 110 and the electrode layer 120, such that the electrode 125 may be formed with one of the insulation layers 110 under the one of the electrode layers 120 that were not removed.

Thus, the first contact plug 150 may be easily formed to contact an upper surface of one of the electrode layers 120 at a desired level in the stack structure. During the formation of the first opening 140 in which the first contact plug 150 is to be formed, damage to the electrode layer 120 and the insulation layer 110 thereunder may be avoided.

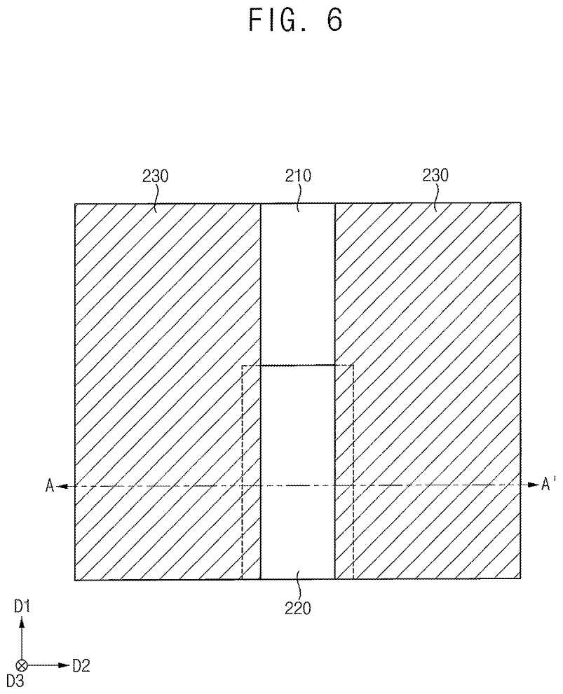

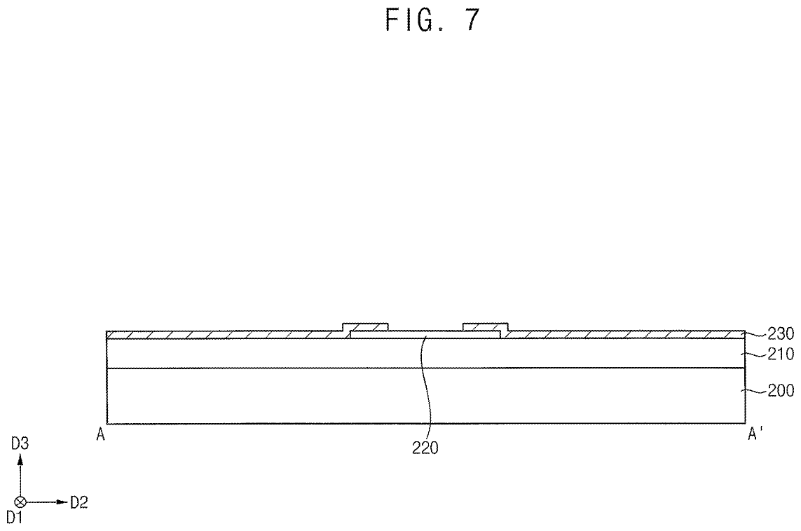

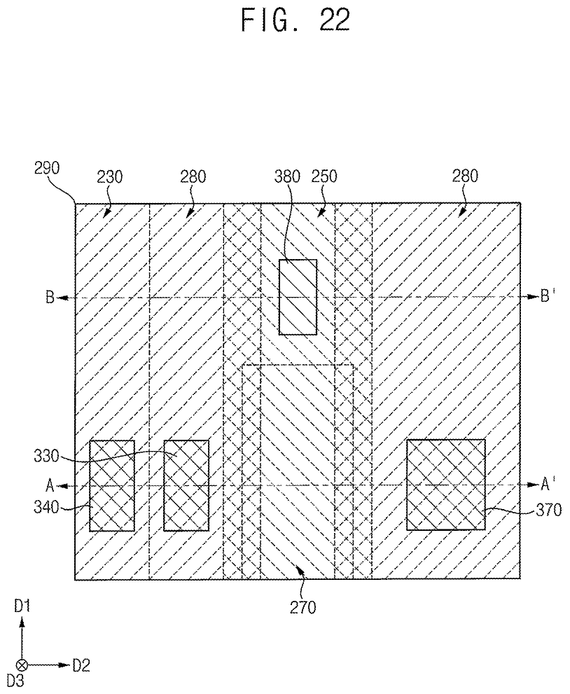

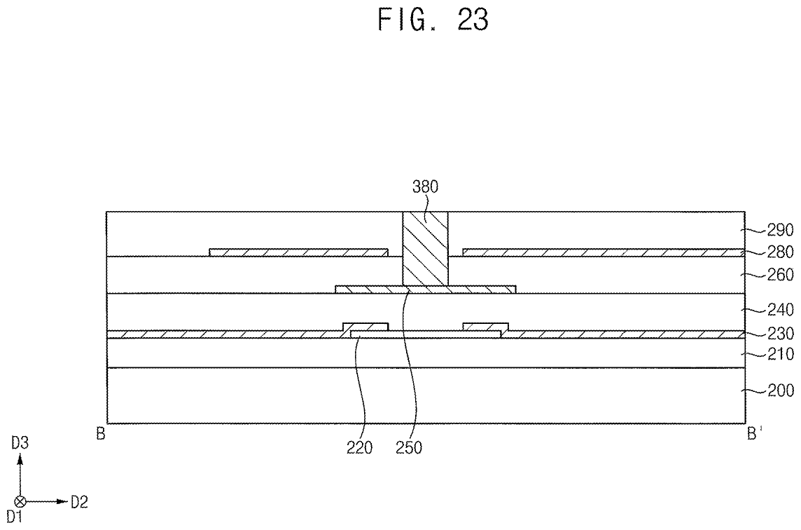

FIGS. 6 to 23 are plan views and cross-sectional views illustrating a method of manufacturing a semiconductor device in accordance with example embodiments. Particularly, FIGS. 6, 8, 10, 12, 14, 16, 18, 20 and 22 are the plan views, FIGS. 7, 9, 11, 13, 15, 17, 19 and 21 are cross-sectional views taken along lines A-A′ of corresponding plan views, and FIG. 23 is a cross-sectional view taken along line B-B′ of FIG. 22.

This method may include processes substantially the same as or similar to those illustrated with reference to FIGS. 1 to 5, and thus repeated explanations thereof are not repeated herein.

Hereinafter, in the specification (and not necessarily in the claims), two horizontal directions substantially parallel to an upper surface of a substrate may be referred to as first and second directions D1 and D2, respectively. A vertical direction substantially perpendicular to the upper surface of the substrate may be referred to as a third direction D3. In example embodiments, the first and second directions D1 and D2 may be substantially perpendicular to each other.

Referring to FIGS. 6 and 7, a first insulation layer 210 may be formed on a substrate 200, a first channel 220 may be formed on the first insulation layer 210, and a first source/drain electrode 230 may be formed on the first channel 220 and the first insulation layer 210.

The substrate 200 may include a semiconductor material, e.g., silicon, germanium, silicon-germanium, etc., or an insulating material, e.g., silicon oxide. The first insulation layer 210 may include, e.g., h-BN, silicon oxide, silicon nitride, etc.

In example embodiments, the first channel 220 may extend in the first direction D1 to a given length on the first insulation layer 210.

In example embodiments, the first channel 220 may include a two-dimensional (2D) material, and for example, a transition metal dichalcogenide (TMD) that may include a transition metal and a chalcogen element. That is, the first channel 220 may include a material that may be represented by a chemical formula MX₂ (M is a transition metal, and X is a chalcogen element).

The transition metal may include, for example, molybdenum (Mo), tungsten (W), rhenium (Re), technetium (Tc), niobium (Nb), tantalum (Ta), hafnium (Hf), zirconium (Zr), osmium (Os), ruthenium (Ru), iridium (Ir), rhodium (Rh), platinum (Pt), palladium (Pd), yttrium (Y), Lanthanum (La), Lutetium (Lu), scandium (Sc), titanium (Ti), vanadium (V), chromium (Cr), Manganese (Mn), iron (Fe), cobalt (Co), nickel (Ni), or the like, and the chalcogen element may include, for example, sulfur (S), selenium (Se), tellurium (Te), or the like.

Thus, the first channel 220 may include a 2D material, for example, molybdenum disulfide (MoS₂), molybdenum diselenide (MoSe₂), molybdenum ditelluride (MoTe₂), tungsten disulfide (WS₂), tungsten diselenide (WSe₂), tungsten ditelluride (WTe₂), or the like.

In an example embodiment, the first channel 220 may include a n-type 2D material, e.g., molybdenum disulfide (MoS₂), molybdenum diselenide (MoSe₂), etc., and thus may serve as a channel of an NMOS transistor.

The first source/drain electrode 230 may be formed at each of opposite sides of the first channel 220 in the second direction D2, and may also be formed on a portion of an upper surface of the first insulation layer 210 adjacent thereto. In example embodiments, the first source/drain electrode 230 may include graphene.

Each of the first channel 220 and the first source/drain electrode 230 may be formed on the first insulation layer 210 by a dry transfer process.

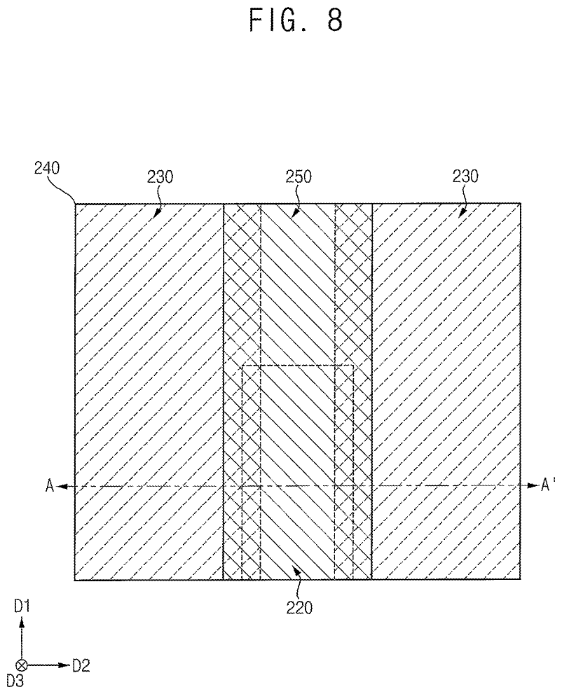

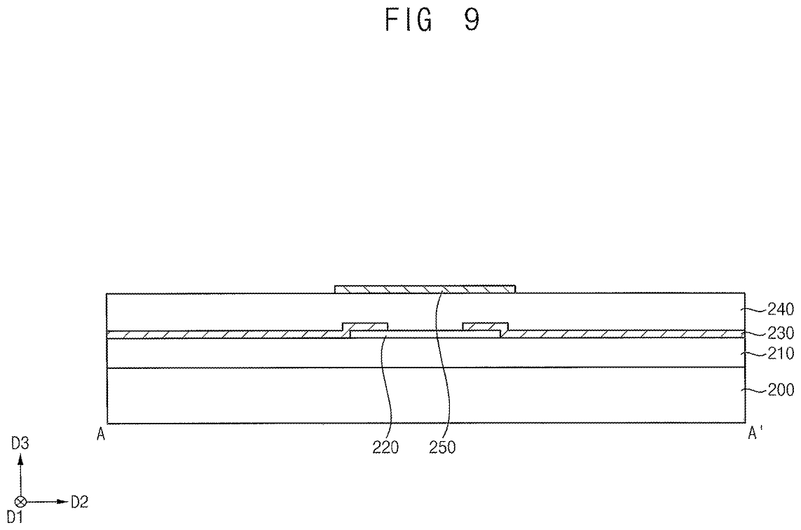

Referring to FIGS. 8 and 9, a second insulation layer 240 may be formed on the first channel 220, the first source/drain electrode 230 and the first insulation layer 210, and a gate electrode 250 may be formed on the second insulation layer 240.

The second insulation layer 240 may include, e.g., h-BN, silicon oxide, silicon nitride, etc., and the gate electrode 250 may include graphene.

In example embodiments, the gate electrode 250 may extend in the first direction D1 on the second insulation layer 240, and may overlap the first channel 220 in the third direction D3. In example embodiments, an extension length of the gate electrode 250 in the first direction D1 may be greater than an extension length of the first channel 220 in the first direction D1.

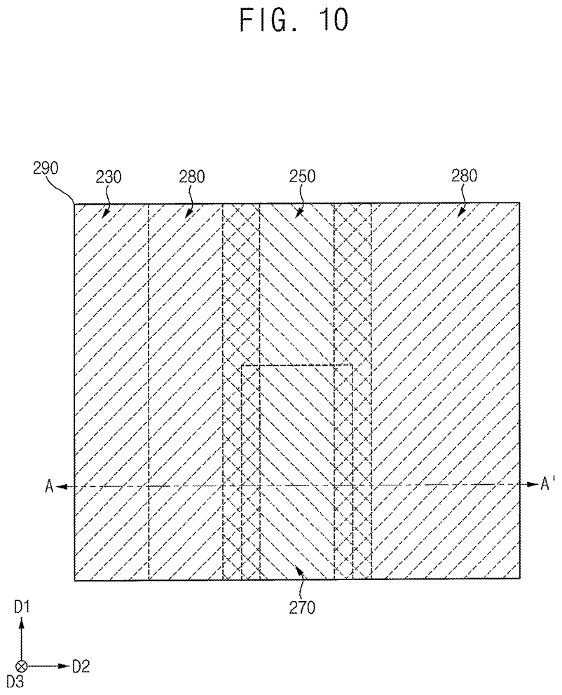

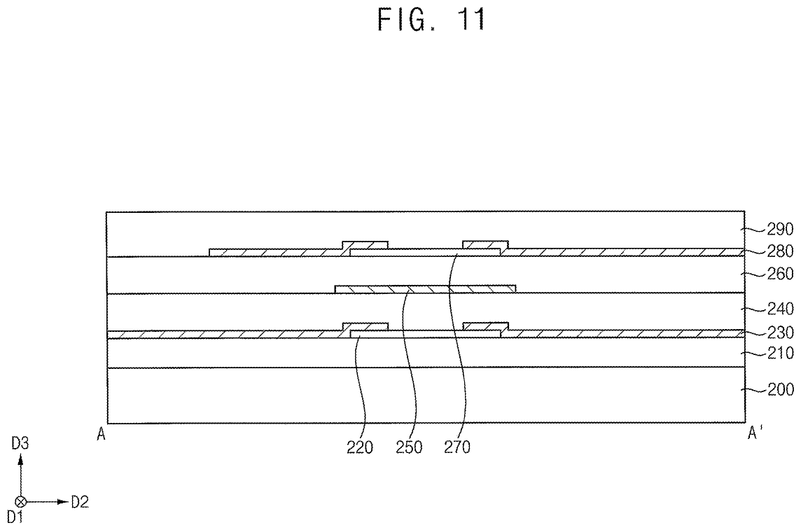

Referring to FIGS. 10 and 11, a third insulation layer 260 may be formed on the gate electrode 250 and the second insulation layer 240, a second channel 270 and a second source/drain electrode 280 may be formed on the third insulation layer 260. A fourth insulation layer 290 may be formed on the second channel 270 and the second source/drain electrode 280.

In example embodiments, the second channel 270 may extend in the first direction D1 to a given length on the third insulation layer 260, and may overlap the gate electrode 250 in the third direction D3. In example embodiments, an extension length of the second channel 270 in the first direction D1 may be less than the extension length of the gate electrode 250 in the first direction D1.

The second source/drain electrode 280 may be formed at each of opposite sides of the second channel 270 in the second direction D2, and may also be formed on a portion of the third insulation layer 260 adjacent thereto.

In example embodiments, a first one of the second source/drain electrodes 280 at a first side of the second channel 270 may have a width in the second direction D2 less than a width in the second direction D2 of a second one of the second source/drain electrodes 280 at a second side of the second channel 270 that is opposite to the first side thereof, and thus the first one of the second source/drain electrodes 280 may overlap only a portion of the first source/drain electrode 230 in the third direction D3. Hereinafter, sides of the first channel 220 overlapped in the third direction D3 by the first and second sides of the second channel 270 may also be referred to as first and second sides, respectively, of the first channel 220.

Each of the third and fourth insulation layers 260 and 290 may include, e.g., h-BN, silicon oxide, silicon nitride, etc., and the second source/drain electrode 280 may include graphene.

The second channel 270 may include a 2D material. In an example embodiment, the second channel 270 may include a p-type 2D material, for example, molybdenum ditelluride (MoTe₂), tungsten disulfide (WS₂), etc., and thus may serve as a channel of a PMOS transistor.

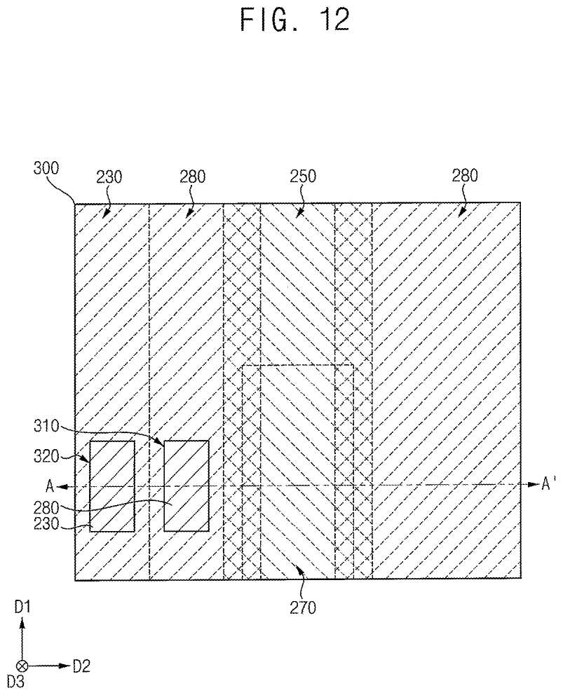

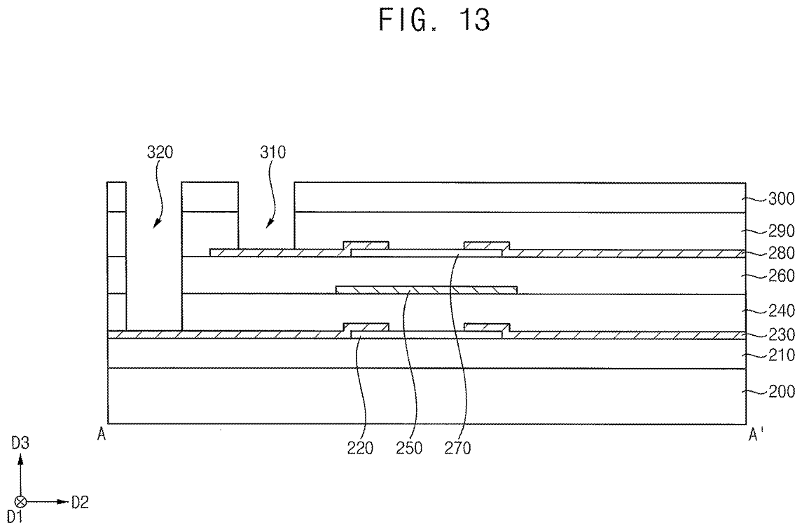

Referring to FIGS. 12 and 13, a second mask 300 may be formed on the fourth insulation layer 290, and a third dry etching process may be performed on the fourth insulation layer 290 using the second mask 300 as an etching mask. Thus, a second opening 310 extending through the fourth insulation layer 290 to expose an upper surface of the first one of the second source/drain electrodes 280 at the first side of the second channel 270, and a third opening 320 extending through the second to fourth insulation layers 240, 260 and 290 to expose an upper surface of a first one of the first source/drain electrodes 230 at the first side of the first channel 220 may be formed.

As illustrated with reference to FIG. 2 or FIG. 4, the third dry etching process may be performed using an etching gas including fluorine (F), e.g., xenon difluoride (XeF₂), carbon tetrafluoride (CF₄), sulfur hexafluoride (SF₆), etc. Thus, the upper surfaces of each of the first and second source/drain electrodes 230 and 280 exposed by the third dry etching process may be fluorinated to form fluorinated graphene, which may serve as an etch stop layer in the third dry etching process. Accordingly, during the third dry etching process, the first and third insulation layers 210 and 260 under the first and second source/drain electrodes 230 and 280 may not be removed.

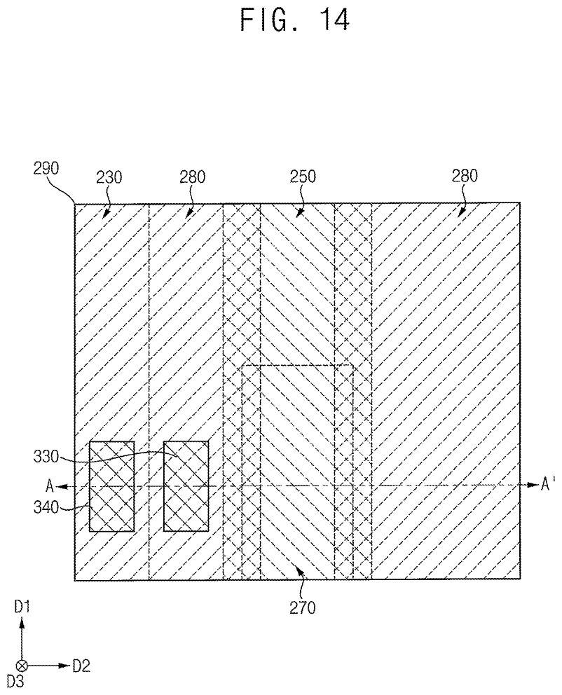

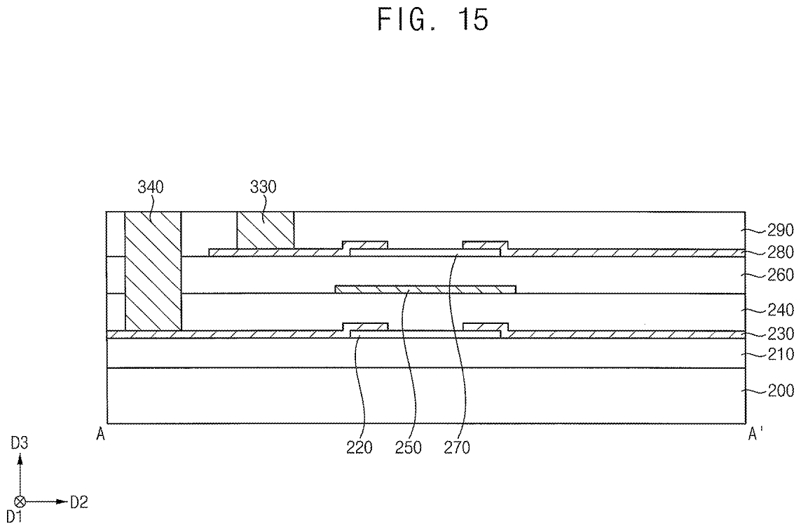

Referring to FIGS. 14 and 15, processes substantially the same as or similar to those illustrated with reference to FIG. 3A or FIG. 5 may be performed to form second and third contact plugs 330 and 340 in the second and third openings 310 and 320, respectively. The second and third contact plugs 330 and 340 may contact the upper surfaces of the second and first source/drain electrodes 280 and 230, respectively.

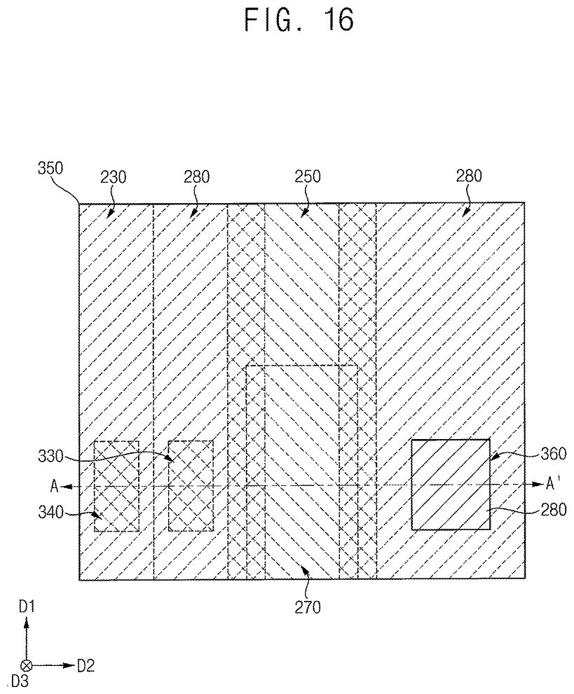

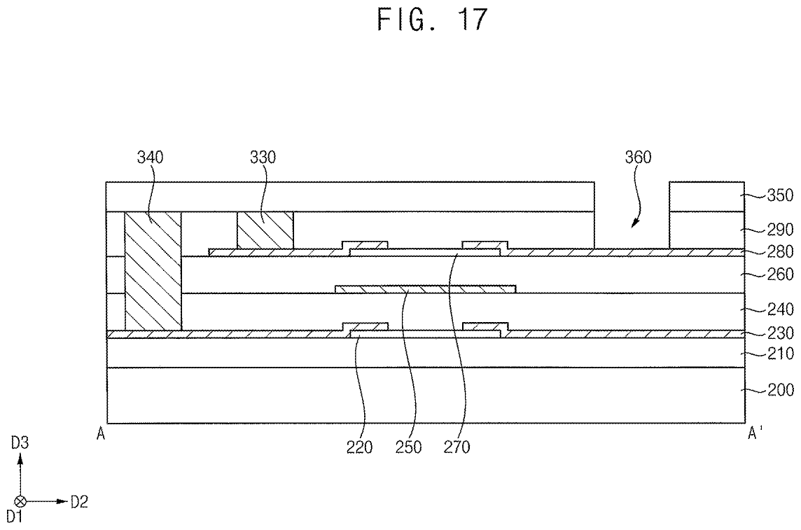

Referring to FIGS. 16 and 17, processes substantially the same as or similar to those illustrated with reference to FIGS. 12 and 13 may be performed.

Particularly, a third mask 350 may be formed on the fourth insulation layer 290 and the second and third contact plugs 330 and 340, and a fourth dry etching process may be performed on the fourth insulation layer 290 using the third mask 350 as an etching mask. Thus, a fourth opening 360 extending through the fourth insulation layer 290 may be formed to expose an upper surface of the second one of the second source/drain electrodes 280 at the second side of the second channel 270.

During the fourth dry etching process, an etching gas including fluorine (F), e.g., xenon difluoride (XeF₂), carbon tetrafluoride (CF₄), sulfur hexafluoride (SF₆), etc., may be used, such that the third insulation layer 260 under the second one of the second source/drain electrodes 280 may not be removed.

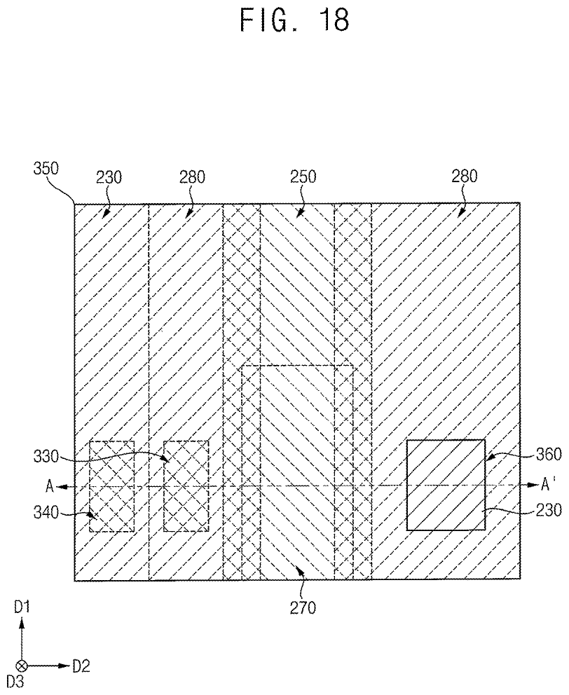

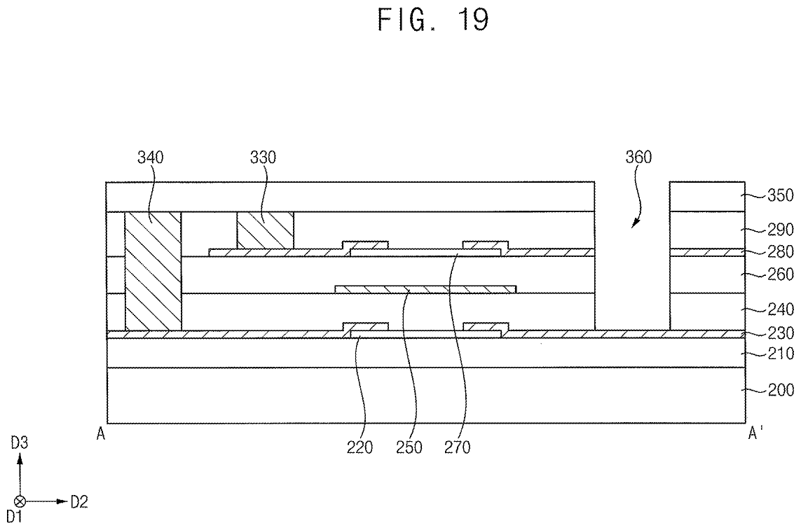

Referring to FIGS. 18 and 19, processes substantially the same as or similar to those illustrated with reference to FIG. 3B or FIG. 4 may be performed.

Particularly, the exposed portion of the second source/drain electrode 280 may be removed by an RIE process using, e.g., oxygen plasma, hydrogen plasma, etc.

A fifth dry etching process may be performed on the second and third insulation layers 240 and 260 using the third mask 350, and the fourth insulation layer 290 and the second source/drain electrode 280 thereunder as an etching mask so that the fourth opening 360 may be enlarged downwardly to expose an upper surface of a second one of the first source/drain electrodes 230 at the second side of the first channel 220.

The fifth dry etching process may be performed using an etching gas including fluorine (F), e.g., xenon difluoride (XeF₂), carbon tetrafluoride (CF₄), sulfur hexafluoride (SF₆), etc., such that the second one of first source/drain electrodes 230 and the first insulation layer 210 under the second one of the first source/drain electrodes 230 may not be removed.

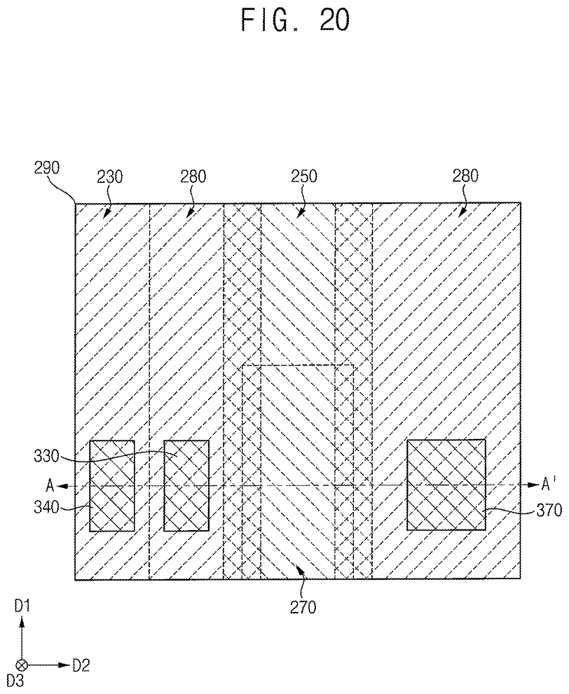

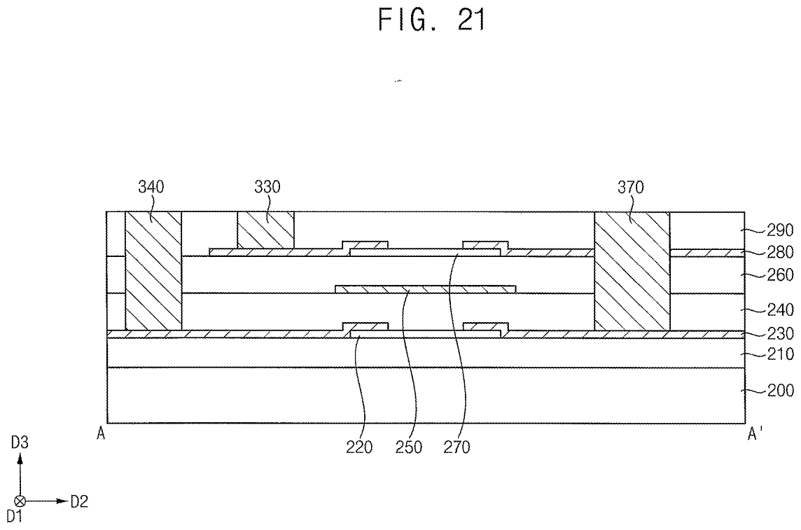

Referring to FIGS. 20 and 21, a fourth contact plug 370 may be formed in the fourth opening 360.

Referring to FIGS. 22 and 23, a fifth contact plug 380 extending through the third and fourth insulation layers 260 and 290 may be formed to contact an upper surface of the gate electrode 250, and thus, the fabrication of the semiconductor device may be completed.

The semiconductor device may include the first insulation layer 210 on the substrate 200, the first channel 220 on the first insulation layer 210, the first source/drain electrodes 230 contacting opposite lateral portions, respectively, in the second direction D2 of the first channel 220 and portions of the first insulation layer 210 adjacent thereto, the second insulation layer 240 covering the first channel 220 and the first source/drain electrode 230 and on the first insulation layer 210, the gate electrode 250 on the second insulation layer 240, the third insulation layer 260 covering the gate electrode 250 and on the second insulation layer 240, the second channel 270 on the third insulation layer 260, the second source/drain electrodes 280 contacting opposite lateral portions, respectively, in the second direction D2 of the second channel 270 and portions of the third insulation layer 260 adjacent thereto, the fourth insulation layer 290 covering the second channel 270 and the second source/drain electrodes 280 and on the third insulation layer 260, the second contact plug 330 extending through the fourth insulation layer 290 to contact the upper surface of the first one of the second source/drain electrodes 280 at the first side of the second channel 270, the third contact plug 340 extending through the second to fourth insulation layers 240, 260 and 290 to contact the upper surface of the first one of the first source/drain electrodes 280, the fourth contact plug 370 extending through the second to fourth insulation layers 240, 260 and 290 and the second one of the second source/drain electrodes 280 at the second side of the second channel 270 to contact the upper surface of the second one of the first source/drain electrodes 230, and the fifth contact plug 380 extending through the third and fourth insulation layers 260 and 290 to contact the upper surface of the gate electrode 250.

In example embodiments, a width in the second direction D2 of the first one of the first source/drain electrodes 230 at the first side of the first channel 220 may be greater than a width in the second direction D2 of the first one of the second source/drain electrodes 280 at the first side of the second channel 270.

In the semiconductor device, the gate electrode 250, the first channel 220 and the first source/drain electrodes 230 may form an NMOS transistor, and the gate electrode 250, the second channel 270 and the second source/drain electrodes 280 may form a PMOS transistor.

That is, the NMOS transistor and the PMOS transistor stacked in the third direction D3 may form a vertical inverter, and the gate electrode 250 may serve as a common gate of the NMOS transistor and the PMOS transistor.

For example, a source voltage (Vss) may be applied through the third contact plug 340 contacting the upper surface of the first one of the first source/drain electrodes 230 at the first side of the first channel 220, and a drain voltage (Vdd) may be applied through the second contact plug 330 contacting the upper surface of the first one of the second source/drain electrodes 280 at the first side of the second channel 270.

Additionally, an input voltage (Vin) may be applied through the fifth contact plug 380 contacting the upper surface of the gate electrode 250, and an output voltage (Vout) may be applied through the fourth contact plug 370 contacting the upper surface of the second one of the first source/drain electrodes 230 at the second side of the first channel 220 and contacting the sidewall of the second one of the second source/drain electrodes 280.

The semiconductor device may also be a vertical inverter including a PMOS transistor and an NMOS transistor stacked in the vertical direction.

In the method of forming the wiring structure in accordance with example embodiments, in which the stack structure includes insulation layers and electrode layers alternately and repeatedly stacked, the upper insulation layer may be selectively etched by a dry etching process using an etching gas including fluorine, which may have an etching selectivity between the insulation layers and the electrode layers. In this case, the electrode layer under the upper insulation layer may not be removed, and further the lower insulation layer may not be removed.

Additionally, an RIE process may be performed using oxygen plasma and hydrogen plasma having an etching selectivity between the insulation layers and the electrode layers such that the upper electrode layer may be selectively etched and such that the electrode may be formed without the lower insulation layer being removed.

Accordingly, the contact plug contacting an upper surface of an electrode layer at a desired level in the stack structure may be easily formed, and during the formation of an opening for forming the contact plug, damage to the electrode layer and the insulation layer thereunder may be avoided.

One or more embodiments may provide a method of forming a wiring structure having improved characteristics.

One or more embodiments may provide a method of manufacturing a semiconductor device having improved characteristics.

One or more embodiments may provide a semiconductor device having improved characteristics.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of forming a wiring structure, the method comprising:
alternately and repeatedly stacking electrode layers and insulation layers on a substrate, the electrode layers including graphene and the insulation layer including hexagonal boron nitride (h-BN);
etching a first insulation layer through a first dry etching process using an etching gas including fluorine (F) to form an opening exposing an upper surface of a first electrode layer, the first insulation layer being an uppermost one of the insulation layers, and the first electrode layer being an uppermost one of the electrode layers;
removing a portion of the first electrode layer exposed by the opening through a reactive ion etching (RIE) process using oxygen plasma and/or hydrogen plasma to enlarge the opening so that an upper surface of a second insulation layer is exposed, the second insulation layer being one of the insulation layers directly under the first electrode layer;
etching the second insulation layer exposed by the opening through a second dry etching process using an etching gas including fluorine (F) to enlarge the opening so that an upper surface of a second electrode layer is exposed, the second electrode layer being one of the electrode layers directly under the second insulation layer; and
forming a contact plug in the enlarged opening.

2. The method as claimed in claim 1, wherein the etching gas includes xenon difluoride (XeF₂), carbon tetrafluoride (CF₄) or sulfur hexafluoride (SF₆).

3. The method as claimed in claim 1, wherein etching the first insulation layer includes forming fluorinated graphene through a reaction between the fluorine (F) included in the etching gas and the first electrode layer.

4. The method as claimed in claim 1, wherein the first electrode layer serves as an etch stop layer in the first dry etching process.

5. The method as claimed in claim 1, wherein the second insulation layer is not removed in the first dry etching process.

6. A method of forming a wiring structure, the method comprising:
forming a first channel on a substrate;
forming first source/drain electrodes on the substrate to cover lateral portions, respectively, of the first channel, each of the first source/drain electrodes including graphene;
forming a first insulation layer on the substrate to cover the first channel and the first source/drain electrodes;
forming a gate electrode on the first insulation layer, the gate electrode including graphene;
forming a second channel on the second insulation layer;
forming second source/drain electrodes on the second insulation layer to cover lateral portions of the second channel, each of the second source/drain electrodes including graphene;
forming a third insulation layer on the second insulation layer to cover the second channel and the second source/drain electrodes;
forming a first contact plug through the third insulation layer to contact an upper surface of a first one of the second source/drain electrodes at a first side of the second channel;
forming a second contact plug through the first to third insulation layers to contact an upper surface of a first one of the first source/drain electrodes at a first side of the first channel;
forming a third contact plug through the first to third insulation layers and a second one of the second source/drain electrodes at a second side of the second channel to contact an upper surface of a second one of the first source/drain electrodes at a second side of the first channel; and
forming a fourth contact plug through the second and third insulation layers to contact an upper surface of the gate electrode.

7. The method as claimed in claim 6, wherein each of the first and second channels includes a 2D material.

8. The method as claimed in claim 7, wherein the first channel includes an n-type 2D material, and the second channel includes a p-type 2D material.

9. The method as claimed in claim 8, wherein:
the first channel includes molybdenum disulfide (MoS₂) or molybdenum diselenide (MoSe₂), and
the second channel includes molybdenum ditelluride (MoTe₂) or tungsten diselenide (WSe₂).

10. The method as claimed in claim 6, wherein each of the first to third insulation layers includes hexagonal boron nitride (h-BN).

11. The method as claimed in claim 6, wherein forming the first contact plug includes:
etching the third insulation layer through a dry etching process using an etching gas including fluorine (F) to form an opening exposing the upper surface of the first one of the second source/drain electrodes at the first side of the second channel; and
forming the first contact plug in the opening.

12. The method as claimed in claim 6, wherein forming the second contact plug includes:
etching the first to third insulation layers through a dry etching process using an etching gas including fluorine (F) to form an opening exposing the upper surface of the first one of the first source/drain electrodes at the first side of the first channel; and
forming the second contact plug in the opening.

13. The method as claimed in claim 6, wherein forming the first contact plug includes:
etching the third insulation layer through a first dry etching process using an etching gas including fluorine (F) to form an opening exposing the upper surface of the second one of the second source/drain electrodes at the second side of the second channel;
removing a portion of the second one of the second source/drain electrode through a reactive ion etching (RIE) process using oxygen plasma or hydrogen plasma to enlarge the opening so that an upper surface of the second insulation layer is exposed;
etching the first and second insulation layers through a second dry etching process using an etching gas including fluorine (F) to enlarge the opening so that the upper surface of the second one of the first source/drain electrodes at the second side of the first channel is exposed; and
forming the third contact plug in the enlarged opening.

14. The method as claimed in claim 13, wherein the etching gas includes xenon difluoride (XeF₂), carbon tetrafluoride (CF₄) or sulfur hexafluoride (SF₆).

15. The method as claimed in claim 13, wherein:
etching the third insulation layer includes forming fluorinated graphene through reaction between the fluorine (F) included in the etching gas and the second one of the second source/drain electrodes, and
etching the first and second insulation layers includes forming fluorinated graphene through reaction between the fluorine (F) included in the etching gas and the second one of the first source/drain electrodes.

16. The method as claimed in claim 13, wherein the second and first source/drain electrodes serve as etch stop layers in the first and second dry etching processes, respectively.

17. A semiconductor device, comprising:
a first insulation layer on a substrate;
a first channel on the first insulation layer;
first source/drain electrodes contacting opposite lateral portions, respectively, of the first channel and portions of the first insulation layer adjacent thereto, each of the first source/drain electrodes including graphene;
a second insulation layer on the first insulation layer, the second insulation layer covering the first channel and the first source/drain electrodes;
a gate electrode on the second insulation layer, the gate electrode including graphene;
a third insulation layer on the second insulation layer, the third insulation layer covering the gate electrode;
a second channel on the third insulation layer;
second source/drain electrodes contacting opposite lateral portions, respectively, of the second channel and portions of the third insulation layer adjacent thereto, each of the second source/drain electrodes including graphene;
a fourth insulation layer on the third insulation layer, the fourth insulation layer covering the second channel and the second source/drain electrodes;
a first contact plug extending through the fourth insulation layer and contacting an upper surface of a first one of the second source/drain electrodes at a first side of the second channel;
a second contact plug extending through the second to fourth insulation layers and contacting an upper surface of the first source/drain electrode at a first side of the first channel;
a third contact plug extending through the second to fourth insulation layers and a second one of the second source/drain electrodes at a second side of the second channel and contacting an upper surface of the first source/drain electrode at a second side of the first channel; and
a fourth contact plug extending through the third and fourth insulation layers and contacting an upper surface of the gate electrode.

18. The semiconductor device as claimed in claim 17, wherein a width of the first one of the first source/drain electrode is greater than a width of the first one of the second source/drain electrode.

19. The semiconductor device as claimed in claim 17, wherein:
the first channel includes molybdenum disulfide (MoS₂) or molybdenum diselenide (MoSe₂), and
the second channel includes molybdenum ditelluride (MoTe₂) or tungsten diselenide (WSe₂).

20. The semiconductor device as claimed in claim 17, wherein each of the first to fourth insulation layers includes hexagonal boron nitride (h-BN).
